(19) United States
(12) Patent Application Publication
(10) Pub. No.: US 2019/0035447 A1
(43) Pub. Date: Jan. 31, 2019

(54) Magnetic tunnel junction with TMR enhancement

(71) Applicant: Beihang University, Beijing (CN)

(72) Inventors: Weisheng Zhao, Beijing (CN); Jiaqi Zhou, Beijing (CN)

(21) Appl. No.: 16/147,463

(22) Filed: Sep. 28, 2018

(30) Foreign Application Priority Data
Jul. 9, 2018 (CN) 201810745670.4

(51) Int. Cl. G11C 11/16; H01L 43/04; H01L 43/10; G11C 11/18

(52) U.S. Cl. CPC G11C 11/161; H01L 43/04; G11C 11/18; G11C 11/1675; G11C 11/1673; H01L 43/10

(57) ABSTRACT

A magnetic tunnel junction (MTJ) includes a first iridium layer, a first tungsten layer, a first ferromagnetic layer, a tunneling barrier layer, a second ferromagnetic layer, a second tungsten layer and a second iridium layer in sequence, wherein the two ferromagnetic layers are respectively a reference layer with a fixed magnetization direction and a free layer with a reversible magnetization direction. When the magnetization direction of the reference layer is parallel to the magnetization direction of the free layer, the MTJ is in a low-resistance state to store a binary digit “0”; when the magnetization direction of the reference layer is anti-parallel to the magnetization direction of the free layer, the MTJ is in a high-resistance state to store a binary digit “1”. The present invention can enhance tunneling magnetoresistance effect by using iridium layer, improve read reliability and reduce writing power consumption of the MTJ.

### CROSS REFERENCE OF RELATED APPLICATION

The present invention claims priority under 35 U.S.C. 119(a-d) to CN 201810745670.4, filed Jul. 9, 2018.

### BACKGROUND OF THE PRESENT INVENTION

### Field of Invention

The present invention relates to a magnetic tunnel junction, which belongs to the field of non-volatile storage and logic technology.

### Description of Related Arts

Spintronics aims to use electronic spin properties to store, transfer, and compute information. Magnetic random access memory (MRAM) based on spintronics is one of the most promising new memories, with the advantages of non-volatile and low power consumption. The magnetic tunnel junction (MTJ) is a basic unit of a magnetic random access memory, and includes a ferromagnetic layer, a tunneling barrier layer and another ferromagnetic layer in sequence. One ferromagnetic layer with a fixed magnetization direction is called the reference layer; another ferromagnetic layer with a reversible magnetization direction is called the free layer; the tunneling barrier layer is mostly made from metal or non-metal oxide materials to produce electron tunneling effect. When the magnetization direction of the reference layer is parallel to that of the free layer, the MTJ exhibits a low-resistance state to store binary digit “0”; when the magnetization direction of the reference layer is antiparallel to that of the free layer, the MTJ exhibits a high-resistance state to store binary digit “1”. The difference between the high-resistance state and the low-resistance state is the tunneling magnetoresistance effect. The tunneling magnetoresistance ratio (TMR) indicates the difference between high and low resistance states and is an important indicator of the MTJ. An MTJ with high TMR is conductive to preparing an MRAM with low power consumption, high density and high reliability. However, at this stage, the TMR is still low and cannot meet industrialization requirements.

In order to protect the ferromagnetic layer from being oxidized as well as optimize the growth process of the ferromagnetic layer, the non-magnetic layer, usually made from heavy metal materials, is adjoined to the ferromagnetic layer, forming a heterojunction of a non-magnetic layer, a ferromagnetic layer, a tunneling barrier layer, another ferromagnetic layer and another non-magnetic layer. The non-magnetic layer has an important influence on the TMR. Namely, the TMR can be improved through utilizing suitable non-magnetic layer materials and optimizing the structure of the MTJ, thus enhancing the reliability while reducing the power consumption of the MRAM.

### SUMMARY OF THE PRESENT INVENTION

In view of the problem that the TMR is low mentioned in the above background, the present invention provides an MTJ which adopts one of an iridium metal element and an iridium metal alloy as a non-magnetic layer, utilizes one of a tungsten metal element and a tungsten metal alloy to prevent the diffusion of heavy metals, and comprises a first iridium layer, a first tungsten layer, a first ferromagnetic layer, a tunneling barrier layer, a second ferromagnetic layer, a second tungsten layer and a second iridium layer in sequence.

Accordingly, the present invention provides an MTJ which comprises a non-magnetic layer, a ferromagnetic layer, a tunneling barrier layer, another ferromagnetic layer and another non-magnetic layer in sequence, wherein: the non-magnetic layer comprises an iridium layer which is made from one of an iridium metal element and an iridium metal alloy, and a tungsten layer which is made from one of a tungsten metal element and a tungsten metal alloy to prevent diffusion of heavy metals, that is, the MTJ comprises a first iridium layer, a first tungsten layer, a first ferromagnetic layer, a tunneling barrier layer, a second ferromagnetic layer, a second tungsten layer and a second iridium layer in sequence; the two ferromagnetic layers are respectively a reference layer with a fixed magnetization direction and a free layer with a reversible magnetization direction; when the magnetization direction of the reference layer is parallel to the magnetization direction of the free layer, the MTJ is in a low-resistance state to store a binary digit “0”; when the magnetization direction of the reference layer is anti-parallel to the magnetization direction of the free layer, the MTJ is in a high-resistance state to store a binary digit “1”.

The first iridium layer is a top electrode, the first tungsten layer is a capping layer, the first ferromagnetic layer is a free layer, the tunneling barrier layer is configured to electron tunneling, the second ferromagnetic layer is a reference layer, the second tungsten layer is a seed layer, and the second iridium layer is a bottom electrode; the iridium layers are configured to enhance the TMR; the tungsten layers are configured to prevent the diffusion of heavy metals for protecting the TMR; a write current is perpendicularly inputted to the MTJ, and the magnetization direction of the free layer is reversed by spin transfer torque effect to achieve data writing; a read current is perpendicularly inputted to the MTJ to achieve readout by tunneling magnetoresistance effect.

Every iridium layer is but not limited to be made from an iridium (Ir) metal element or an iridium metal alloy, such as iridium manganese (IrMn) alloy and platinum iridium (PtIr) alloy; a thickness of every iridium layer is in a range of 0.2 to 100 nm.

Every tungsten layer is but not limited to be made from a tungsten (W) metal element or a tungsten metal alloy, such as copper tungsten (CuW) alloy and molybdenum tungsten (MoW) alloy; a thickness of every tungsten layer is in a range of 0.2 to 10 nm.

Every ferromagnetic layer is but not limited to be made from an elemental ferromagnetic metal such as iron (Fe), cobalt (Co) and nickel (Ni); an iron cobalt nickel alloy such as permalloy (NiFe), cobalt iron boron (CoFeB) alloy and iron platinum (FePt) alloy; a ferromagnetic material with half-metal property such as cobalt iron aluminum (CoFeAlₓ) Heusler or semi-Heusler alloy; or a magnetic metal oxide such as iron oxide (FeOₓ) and chromium oxide (CrOₓ); a thickness of every ferromagnetic layer is in a range of 0.2 to 10 nm.

The tunneling barrier layer is but not limited to be made from one of metal or non-metal oxides, such as magnesium oxide (MgO), aluminum oxide (AlOₓ), titanium oxide (TiOₓ), and silicon oxide (SiOₓ); a thickness of the tunneling barrier layer is in a range of 0.2 to 10 nm.

Furthermore, an electrode is introduced to a plane where the second tungsten layer is located for the write current input; the iridium layers are able to enhance the TMR; the tungsten layers are configured to prevent the diffusion of heavy metals for protecting the TMR; the write current is inputted to the second tungsten layer for generating spin orbit torque using spin Hall effect, so as to reverse the second ferromagnetic layer for finally achieving data writing; a read current is inputted to a vertical direction of the MTJ to achieve data readout using tunneling magnetoresistance effect; the magnetization direction of every ferromagnetic layer, a direction of the write current and a direction of the read current are perpendicular to each other.

Thicknesses of every iridium layer, every tungsten layer, every ferromagnetic layer and the tunneling barrier layer are respectively as the same as those mentioned above.

Furthermore, the first ferromagnetic layer comprises a first ferromagnetic sub-layer, a non-magnetic insertion layer and a second ferromagnetic sub-layer in sequence, three of which acts as a free layer; the second ferromagnetic layer is a reference layer; so that the MTJ comprises a first iridium layer, a first tungsten layer, a first ferromagnetic sub-layer, a non-magnetic insertion layer, a second ferromagnetic sub-layer, a tunneling barrier layer, a second ferromagnetic layer, a second tungsten layer and a second iridium layer from top to bottom in sequence; the iridium layers are able to enhance the TMR; the tungsten layers are configured to prevent diffusion of heavy metals for protecting the TMR; a write current is perpendicularly inputted to the MTJ, one ferromagnetic sub-layer is firstly reversed by spin transfer torque effect, another ferromagnetic sub-layer is driven to be reversed by ferromagnetic coupling effect, so as to finally reverse the whole free layer, thus achieving data writing and reducing writing power consumption; a read current is inputted to the vertical direction of the MTJ, the data are read out by the tunneling magnetoresistance effect.

Thicknesses of every iridium layer, every tungsten layer, every ferromagnetic layer and the tunneling barrier layer are respectively as the same as those mentioned above.

The non-magnetic insertion layer is a non-magnetic thin layer which is but not limited to one of metal or non-metal oxides, such as MgO, AlOₓ, TiOₓ, and SiOₓ; one of non-magnetic metals or related alloys, such as tantalum (Ta), ruthenium (Ru) and copper (Cu); nonmetals or related compounds such as silicon (Si) and germanium (Ge); a thickness of the non-magnetic insertion layer is in a range of 0.2 to 10 nm.

The MTJ provided by the present invention has advantages of generating high TMR, improving read reliability and reducing writing power consumption.

### BRIEF DESCRIPTION OF THE DRAWINGS

FIG. 1 is a structural diagram of an MTJ based on spin transfer torque and a combined structure of an iridium layer and a tungsten layer according to a first preferred embodiment of the present invention.

FIG. 2 is a structural diagram of an MTJ based on spin orbit torque and a combined structure of an iridium layer and a tungsten layer according to a second preferred embodiment of the present invention.

FIG. 3 is a structural diagram of an MTJ based on a double-free-layer and a combined structure of an iridium layer and a tungsten layer according to a third preferred embodiment of the present invention.

FIG. 4 is a structural diagram of an MTJ based on spin transfer torque and an iridium layer according to a fourth preferred embodiment of the present invention.

FIG. 5 is a structural diagram of an MTJ based on spin orbit torque and an iridium layer according to a fifth preferred embodiment of the present invention.

FIG. 6 is a structural diagram of an MTJ based on a double-free-layer and an iridium layer according to a sixth preferred embodiment of the present invention.

### DETAILED DESCRIPTION OF THE PREFERRED EMBODIMENT

The present invention provides a magnetic tunnel junction (MTJ). In specific embodiments of the present invention, through designing the material made into the MTJ and the structure of the MTJ, the tunneling magnetoresistance ratio (TMR) is enhanced, which is conductive to improving the key performance of magnetic random access memory such as high reliability and low power consumption.

The essential features of the present invention will be further described with reference to the accompanying drawings. The drawings are schematic diagrams in which the thickness of each functional layer or region involved is not the actual size, and the distance between functional regions is not the actual value.

### First Embodiment

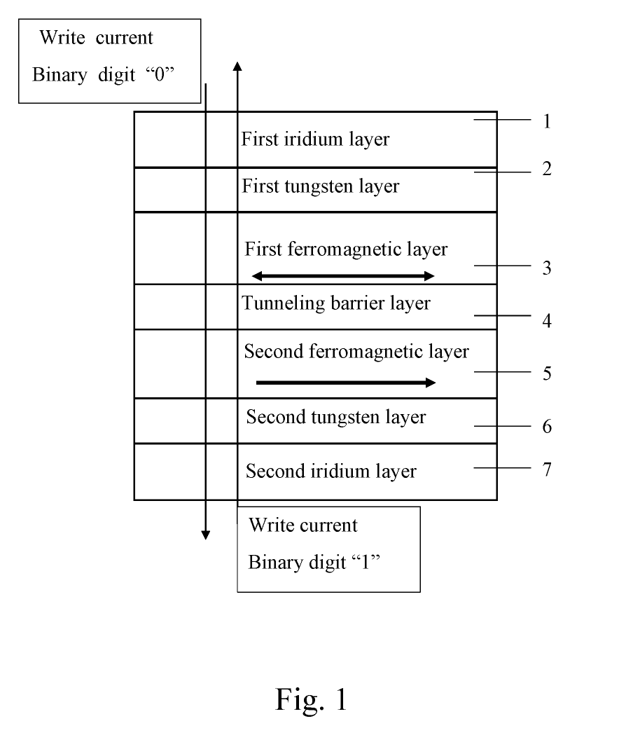

FIG. 1 is a structural diagram of an MTJ according to a first preferred embodiment of the present invention. The MTJ comprises a first iridium layer, a first tungsten layer, a first ferromagnetic layer, a tunneling barrier layer, a second ferromagnetic layer, a second tungsten layer and a second iridium layer from top to bottom in sequence. The first iridium layer 1 acts as a top electrode. The first tungsten layer 2 is a capping layer for protecting the first ferromagnetic layer 3 from being oxidized. The first ferromagnetic layer 3 is a free layer with a reversible magnetization direction which is reversed with a spin transfer torque by inputting a write current along a vertical direction of the MTJ. When the write current is inputted along the vertical direction of the MTJ from top to bottom, the MTJ transforms from an anti-parallel state to a parallel state, so that a low-resistance state is formed, thus a binary digit “0” is written into the MTJ; when the write current is inputted along the vertical direction of the MTJ from bottom to top, the MTJ transforms from the parallel state to the anti-parallel state, so that a high-resistance state is formed, thereby a binary digit “1” is written into the MTJ. The tunneling barrier layer 4 is configured to generate a tunneling current. The second ferromagnetic layer 5 is a reference layer with a fixed magnetization direction. The second tungsten layer 6 is a seed layer for optimizing a growth process of the second ferromagnetic layer 5. The second iridium layer 7 acts as a bottom electrode. The difference between the high-resistance state and the low-resistance state is the tunneling magnetoresistance effect, by which stored data are able to be read out. Due to a combined structure of the iridium layer and the tungsten layer, the MTJ has a characteristic of high TMR. When a read current is inputted along the vertical direction of the MTJ, the data are read out by the tunneling magnetoresistance effect. The magnetization direction of the ferromagnetic layer is shown in FIG. 1, in which the magnetization direction of the first ferromagnetic layer 3 is able to be parallel to a paper surface toward a left side or a right side of FIG. 1, and the magnetization direction of the second ferromagnetic layer 5 is parallel to the paper surface toward the right side of FIG. 1. A direction of the write current is parallel to a direction of the read current, each of which is parallel to the paper surface from top to bottom or from bottom to top.

In the first embodiment, the first iridium layer 1 is made from an iridium (Ir) metal element and has a thickness of 80 nm; the first tungsten layer 2 is made from a tungsten (W) metal element and has a thickness of 2 nm; the first ferromagnetic layer 3 is made from a cobalt iron boron (CoFeB) alloy and has a thickness of 2 nm; the tunneling barrier layer 4 is made from an aluminum oxide (AlOₓ) material and has a thickness of 1.2 nm; the second ferromagnetic layer 5 is made from a CoFeB alloy and has a thickness of 5 nm; the second tungsten layer 6 is made from a W metal element and has a thickness of 1 nm; and the second iridium layer 7 is made from an Ir metal element and has a thickness of 40 nm.

In the first embodiment, through molecular beam epitaxy, magnetron sputtering and other methods, in a bottom-up order, the second iridium layer 7, the second tungsten layer 6, the second ferromagnetic layer 5, the tunneling barrier layer 4, the first ferromagnetic layer 3, the first tungsten layer 2 and the first iridium layer 1 are deposited on a substrate in sequence; and then a subsequent protection and anti-oxidation treatment is performed, and electrodes are respectively introduced along a vertical direction of the second iridium layer 7 and the first iridium layer 1 for respectively inputting the write current and the read current; and finally, etching is preformed to obtain the MTJ, wherein a cross section of the MTJ is circular or elliptical.

### Second Embodiment

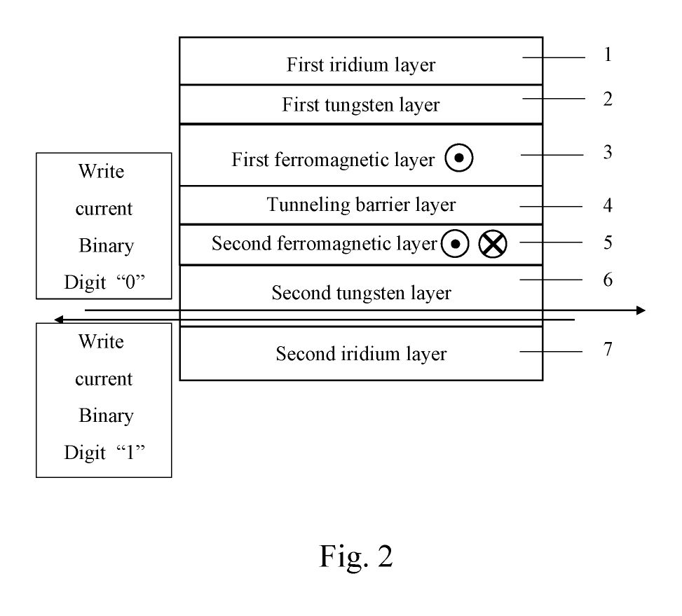

FIG. 2 is a structural diagram of an MTJ according to a second preferred embodiment of the present invention. The MTJ comprises a first iridium layer, a first tungsten layer, a first ferromagnetic layer, a tunneling barrier layer, a second ferromagnetic layer, a second tungsten layer and a second iridium layer from top to bottom in sequence. The first iridium layer 1 acts as a top electrode. The first tungsten layer 2 is a capping layer for protecting the first ferromagnetic layer 3 from being oxidized. The first ferromagnetic layer 3 is a reference layer with a fixed magnetization direction. The tunneling barrier layer 4 is configured to generate a tunneling current. The second ferromagnetic layer 5 is a free layer with a variable magnetization direction. The second tungsten layer 6 is a seed layer for optimizing a growth process of the second ferromagnetic layer 5. The second iridium layer 7 acts as a bottom electrode. An electrode is drawn out from a plane where the second tungsten layer 6 is located for inputting a write current. Due to spin Hall effect, the second tungsten layer 6 is able to generate a spin orbit torque. When the write current is horizontally inputted from a left side to a right side of FIG. 2, the MTJ transforms from an anti-parallel state to a parallel state, so that a low-resistance state is formed, thus a binary digit “0” is written into the MTJ; when the write current is horizontally inputted from the right side to the left side of FIG. 2, the MTJ transforms from the parallel state to the anti-parallel state, so that a high-resistance state is formed, thus a binary digit “1” is written into the MTJ. The difference between the high-resistance state and the low-resistance state is the tunneling magnetoresistance effect, by which stored data are able to be read out. Due to a combined structure of the iridium layer and the tungsten layer, the MTJ has a characteristic of high TMR and is further reduced in write power consumption using the spin orbit torque. When a read current (not shown in FIG. 2) is inputted along the vertical direction of the MTJ, the data are read out by the tunneling magnetoresistance effect. The magnetization direction of every ferromagnetic layer (as shown in FIG. 2, the magnetization direction of the first ferromagnetic layer 3 is inwardly perpendicular to a paper surface, and the magnetization direction of the second ferromagnetic layer 5 is able to be inwardly or outwardly perpendicular to the paper surface), a direction of the write current and a direction of the read current are perpendicular to each other.

In the second embodiment, the first iridium layer 1 is made from an iridium manganese (IrMn) alloy and has a thickness of 5 nm; the first tungsten layer 2 is made from a W metal element and has a thickness of 1 nm; the first ferromagnetic layer 3 is made from a cobalt iron (CoFe) alloy and has a thickness of 5 nm; the tunneling barrier layer 4 is made from a titanium oxide (TiOₓ) material and has a thickness of 1 nm; the second ferromagnetic layer 5 is made from a CoFeB alloy and has a thickness of 2 nm; the second tungsten layer 6 is made from a W metal element and has a thickness of 6 nm; and the second iridium layer 7 is made from an IrMn alloy and has a thickness of 8 nm.

In the second embodiment, through molecular beam epitaxy, magnetron sputtering and other methods, in a bottom-up order, the second iridium layer 7, the second tungsten layer 6, the second ferromagnetic layer 5, the tunneling barrier layer 4, the first ferromagnetic layer 3, the first tungsten layer 2 and the first iridium layer 1 are deposited on a substrate in sequence; and then a subsequent protection and anti-oxidation treatment is performed, an electrode is introduced to the plane where the second tungsten layer 6 is located for inputting the write current, and electrodes are respectively introduced to the vertical direction of the second iridium layer 7 and the first iridium layer 1 for inputting the read current; and finally, etching is preformed to obtain the MTJ, wherein a cross section of the MTJ is circular or elliptical.

### Third Embodiment

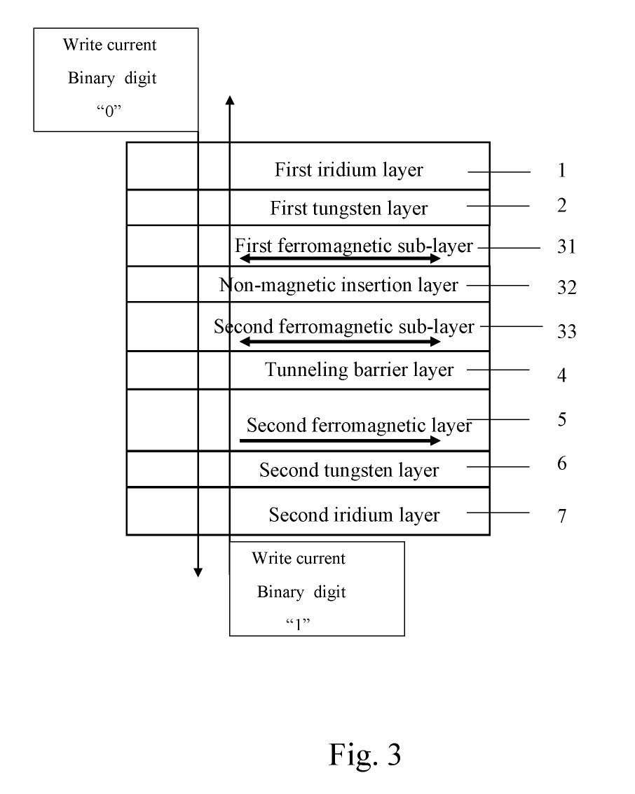

FIG. 3 is a structural diagram of an MTJ according to a third preferred embodiment of the present invention. The MTJ comprises a first iridium layer, a first tungsten layer, a first ferromagnetic sub-layer, a non-magnetic insertion layer, a second ferromagnetic sub-layer, a tunneling barrier layer, a second ferromagnetic layer, a second tungsten layer and a second iridium layer from top to bottom in sequence, wherein a combined structure of the first ferromagnetic sub-layer, the non-magnetic insertion layer and the second ferromagnetic sub-layer is a free layer, the second ferromagnetic layer is a reference layer. The first iridium layer 1 acts as a top electrode. The first tungsten layer 2 is a capping layer for protecting the first ferromagnetic sub-layer 31 from being oxidized. The non-magnetic insertion layer 32 is configured to ferromagnetic coupling between the first ferromagnetic sub-layer 31 and the second ferromagnetic sub-layer 33. The tunneling barrier layer 4 is configured to generate an electron tunneling effect. The second ferromagnetic layer 5 is a reference layer with a fixed magnetization direction. The second tungsten layer 6 is a seed layer for optimizing a growth process of the second ferromagnetic layer 5. The second iridium layer 7 acts as a bottom electrode. A magnetization direction of the combined structure of the first ferromagnetic sub-layer, the non-magnetic insertion layer and the second ferromagnetic sub-layer is reversed with a spin transfer torque by inputting a write current to a vertical direction of the MTJ. When the MTJ is in a parallel state, the write current is inputted from bottom to top, the magnetization direction of the first ferromagnetic sub-layer 31 is firstly reversed; due to the ferromagnetic coupling effect, the magnetization direction of the second ferromagnetic sub-layer 33 is correspondingly reversed with that of the first ferromagnetic sub-layer 31, the MTJ transforms from the parallel state to an anti-parallel state, so that a high-resistance state is formed, thus a binary digit “1” is written into the MTJ. When the MTJ is in the anti-parallel state, the write current is inputted from top to bottom, the magnetization direction of the second ferromagnetic sub-layer 33 is firstly reversed; due to the ferromagnetic coupling effect, the magnetization direction of the first ferromagnetic sub-layer 31 is correspondingly reversed with that of the second ferromagnetic sub-layer 33, the MTJ transforms from the anti-parallel state to the parallel state, so that a low-resistance state is formed, thus the binary digit “0” is written into the MTJ. Due to a combined structure of the iridium layer and the tungsten layer, the MTJ has a characteristic of high TMR. The double-free-layer structure is conductive to reducing the write current so as to achieve low write power consumption. When a read current (not shown in FIG. 3) is inputted along the vertical direction of the MTJ, the data are read out by the tunneling magnetoresistance effect. The magnetization direction of the ferromagnetic layer is shown in FIG. 3, wherein the magnetization direction of the first ferromagnetic sub-layer 31 is as same as the magnetization direction of the second ferromagnetic sub-layer 33, each of which is able to be parallel to a paper surface toward a left or right side of FIG. 3. In FIG. 3, the magnetization direction of the second ferromagnetic layer 5 is parallel to the paper surface toward the right side of FIG. 3. A direction of the write current is parallel to a direction of the read current, each of which is parallel to the paper surface from top to bottom or from bottom to top.

In the third embodiment, the first iridium layer 1 is made from an platinum iridium (PtIr) alloy and has a thickness of 50 nm; the first tungsten layer 2 is made from a molybdenum tungsten (MoW) alloy and has a thickness of 7 nm; the first ferromagnetic sub-layer 31 is made from a CoFeB alloy and has a thickness of 0.8 nm; the non-magnetic insertion layer 32 is made from a molybdenum (Mo) metal element and has a thickness of 0.4 nm; the second ferromagnetic sub-layer 33 is made from a CoFeB alloy and has a thickness of 0.8 nm; the tunneling barrier layer 4 is made from a MgO material and has a thickness of 2 nm; the second ferromagnetic layer 5 is made from an iron platinum (FePt) alloy and has a thickness of 6 nm; the second tungsten layer 6 is made from a W metal element and has a thickness of 3 nm; and the second iridium layer 7 is made from an Ir metal element and has a thickness of 50 nm.

In the third embodiment, through molecular beam epitaxy, magnetron sputtering and other methods, in a bottom-up order, the second iridium layer 7, the second tungsten layer 6, the second ferromagnetic layer 5, the tunneling barrier layer 4, the second ferromagnetic sub-layer 33, the non-magnetic insertion layer 32, the first ferromagnetic sub-layer 31, the first tungsten layer 2 and the first iridium layer 1 are deposited on a substrate in sequence; and then a subsequent protection and anti-oxidation treatment is performed; and then electrodes are respectively introduced to the vertical direction of the second iridium layer 7 and the first iridium layer 1 for inputting the write current and the read current; and finally, etching is preformed to obtain the MTJ, wherein a cross section of the MTJ is circular or elliptical.

### Fourth Embodiment

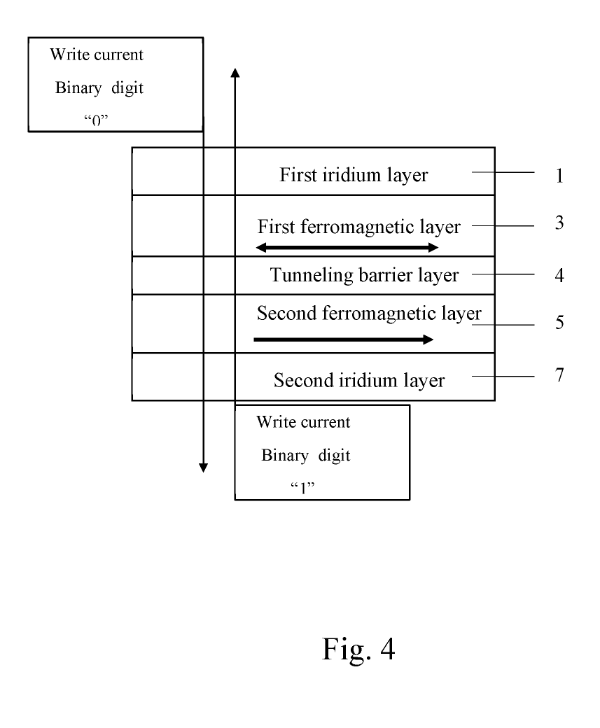

FIG. 4 is a structural diagram of an MTJ according to a fourth preferred embodiment of the present invention. The MTJ comprises a first iridium layer, a first ferromagnetic layer, a tunneling barrier layer, a second ferromagnetic layer, and a second iridium layer from top to bottom in sequence. The first iridium layer 1 acts as both a top electrode and a capping layer for protecting the first ferromagnetic layer 3 from being oxidized. The first ferromagnetic layer 3 is a free layer with a reversible magnetization direction which is reversed with a spin transfer torque by inputting a write current along a vertical direction of the MTJ. When the write current is inputted along the vertical direction of the MTJ from top to bottom, the MTJ transforms from an anti-parallel state to a parallel state, so that a low-resistance state is formed, thus a binary digit “0” is written into the MTJ; when the write current is inputted along the vertical direction of the MTJ from bottom to top, the MTJ transforms from the parallel state to the anti-parallel state, so that a high-resistance state is formed, thus a binary digit “1” is written into the MTJ. The tunneling barrier layer 4 is configured to generate a tunneling current. The second ferromagnetic layer 5 is a reference layer with a fixed magnetization direction. The second iridium layer 7 acts as both a bottom electrode and a seed layer for optimizing a growth process of the second ferromagnetic layer 5. The difference between the high-resistance state and the low-resistance state is the tunneling magnetoresistance effect, by which stored data are able to be read out. Due to the iridium electrode material, the MTJ has a characteristic of high TMR. When a read current (not shown in FIG. 4) is inputted to the vertical direction of the MTJ, the data are read out by the tunneling magnetoresistance effect. The magnetization direction of the ferromagnetic layer is to shown in FIG. 4, in which the magnetization direction of the first ferromagnetic layer 3 is able to be parallel to a paper surface toward a left side or a right side of FIG. 4, and the magnetization direction of the second ferromagnetic layer 5 is parallel to the paper surface toward the right side of FIG. 4. A direction of the write current is parallel to a direction of the read current, each of which is parallel to the paper surface from top to bottom or from bottom to top.

In the fourth embodiment, the first iridium layer 1 is made from an IrMn alloy and has a thickness of 5 nm; the first ferromagnetic layer 3 is made from a permalloy (NiFe) alloy and has a thickness of 8 nm; the tunneling barrier layer 4 is made from AlOₓ material and has a thickness of 2 nm; the second ferromagnetic layer 5 is made from a cobalt iron aluminum (Co₂FeAl) alloy and has a thickness of 5 nm; and the second iridium layer 7 is made from an IrMn alloy and has a thickness of 5 nm.

In the fourth embodiment, through molecular beam epitaxy, magnetron sputtering and other methods, in a bottom-up order, the second iridium layer 7, the second ferromagnetic layer 5, the tunneling barrier layer 4, the first ferromagnetic layer 3, and the first iridium layer 1 are deposited on a substrate in sequence; and then a subsequent protection and anti-oxidation treatment is performed; and then electrodes are respectively introduced to the vertical direction of the second iridium layer 7 and the first iridium layer 1 for respectively inputting the write current and the read current; and finally, etching is preformed to obtain the MTJ, wherein a cross section of the MTJ is circular or elliptical.

### Fifth Embodiment

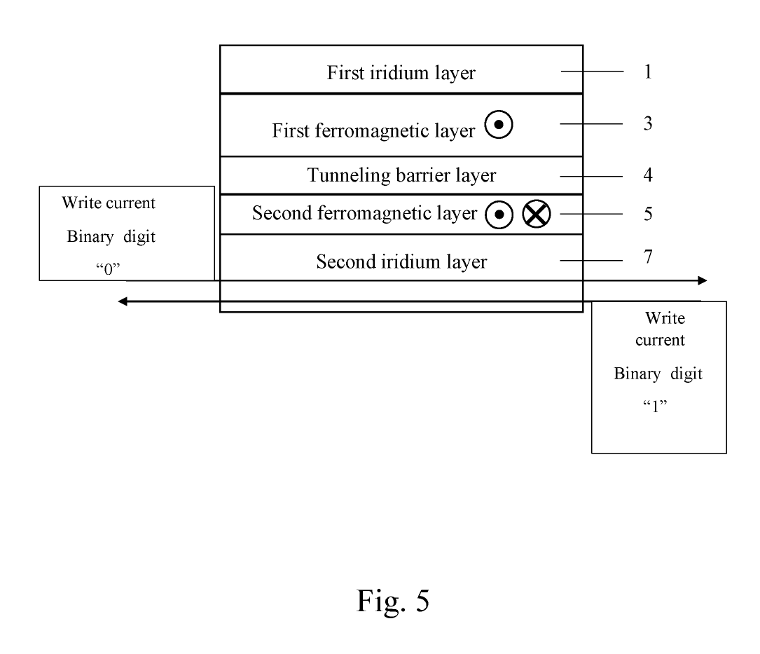

FIG. 5 is a structural diagram of an MTJ according to a fifth preferred embodiment of the present invention. The MTJ comprises a first iridium layer, a first ferromagnetic layer, a tunneling barrier layer, a second ferromagnetic layer, and a second iridium layer from top to bottom in sequence. The first iridium layer 1 acts as both a top electrode and a capping layer for protecting the first ferromagnetic layer 3 from being oxidized. The first ferromagnetic layer 3 is a reference layer with a fixed magnetization direction. The tunneling barrier layer 4 is configured to generate a tunneling current. The second ferromagnetic layer 5 is a free layer with variable magnetization direction. The second iridium layer 7 acts as both a bottom electrode and a seed layer for optimizing a growth process of the second ferromagnetic layer 5. An electrode is drawn out from a plane where the second iridium layer 7 is located for inputting a write current. Due to spin Hall effect, the second iridium layer 7 is able to generate a spin orbit torque. When the write current is horizontally inputted from a left side to a right side of FIG. 5, the MTJ transforms from an anti-parallel state to a parallel state, so that a low-resistance state is formed, thus a binary digit “0” is written into the MTJ; when the write current is horizontally inputted from the right side to the left side of FIG. 5, the MTJ transforms from the parallel state to the anti-parallel state, so that a high-resistance state is formed, thus a binary digit “1” is written into the MTJ. The difference between the high-resistance state and the low-resistance state is the tunneling magnetoresistance effect, by which stored data are able to be read out. Due to the iridium electrode material, the MTJ has a characteristic of high TMR and is further reduced in write power consumption using the spin orbit torque. The magnetization direction of every ferromagnetic layer (as shown in FIG. 5, the magnetization direction of the first ferromagnetic layer 3 is inwardly perpendicular to a paper surface, and the magnetization direction of the second ferromagnetic layer 5 is able to be inwardly or outwardly perpendicular to the paper surface), a direction of the write current and a direction of the read current are perpendicular to each other.

In the fifth embodiment, the first iridium layer 1 is made from an Ir metal element and has a thickness of 70 nm; the first ferromagnetic layer 3 is made from a cobalt (CoFe) metal element and has a thickness of 5 nm; the tunneling barrier layer 4 is made from a MgO material and has a thickness of 4 nm; the second ferromagnetic layer 5 is made from an iron (Fe) metal element and has a thickness of 2 nm; and the second iridium layer 7 is made from an Ir metal element and has a thickness of 80 nm.

In the fifth embodiment, through molecular beam epitaxy, magnetron sputtering and other methods, in a bottom-up order, the second iridium layer 7, the second ferromagnetic layer 5, the tunneling barrier layer 4, the first ferromagnetic layer 3, and the first iridium layer 1 are deposited on a substrate in sequence; and then a subsequent protection and anti-oxidation treatment is performed; and then an electrode is introduced into a plane where the second iridium layer 7 is located for inputting a write current, electrodes are respectively introduced to the vertical direction of the second iridium layer 7 and the first iridium layer 1 for inputting the read current; and finally, etching is preformed to obtain the MTJ, wherein a cross section of the MTJ is circular or elliptical.

### Sixth Embodiment

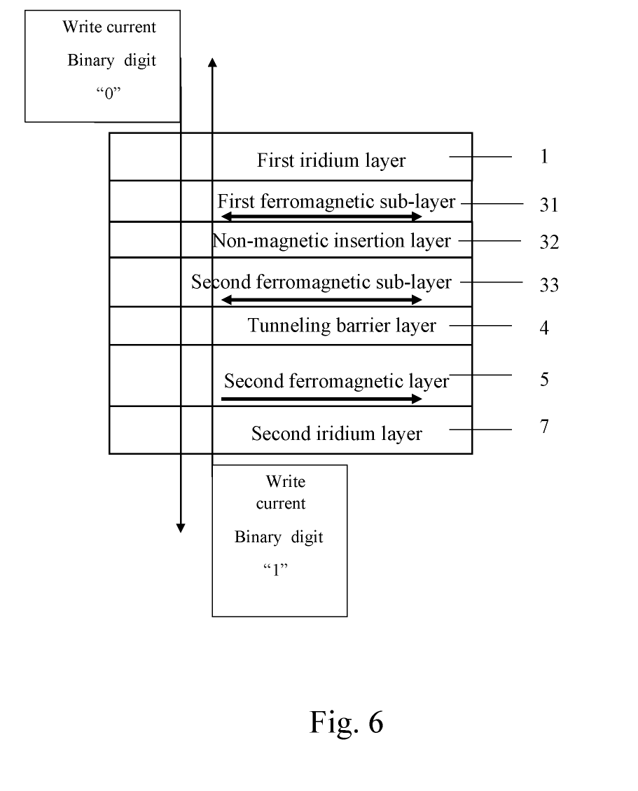

FIG. 6 is a structural diagram of an MTJ according to a sixth preferred embodiment of the present invention. The MTJ comprises a first iridium layer, a first ferromagnetic sub-layer, a non-magnetic insertion layer, a second ferromagnetic sub-layer, a tunneling barrier layer, a second ferromagnetic layer and a second iridium layer from top to bottom in sequence, wherein a combined structure of the first ferromagnetic sub-layer, the non-magnetic insertion layer and the second ferromagnetic sub-layer is a free layer, the second ferromagnetic layer is a reference layer. The first iridium layer 1 acts as both a top electrode and a capping layer for protecting the first ferromagnetic sub-layer 31 from being oxidized. The non-magnetic insertion layer 32 is configured to ferromagnetic coupling between the first ferromagnetic sub-layer 31 and the second ferromagnetic sub-layer 33. The tunneling barrier layer 4 is configured to generate an electron tunneling effect. The second ferromagnetic layer 5 is a reference layer with a fixed magnetization direction. The second iridium layer 7 acts as both a bottom electrode and a seed layer for optimizing a growth process of the second ferromagnetic layer 5. A magnetization direction of the combined structure of the first ferromagnetic sub-layer, the non-magnetic insertion layer and the second ferromagnetic sub-layer is reversed with a spin transfer torque by inputting a write current along a vertical direction of the MTJ. When the MTJ is in a parallel state, the write current is inputted along the vertical direction of the MTJ from bottom to top, the magnetization direction of the first ferromagnetic sub-layer 31 is firstly reversed; due to the ferromagnetic coupling effect, the magnetization direction of the second ferromagnetic sub-layer 33 is correspondingly reversed with that of the first ferromagnetic sub-layer 31, the MTJ transforms from the parallel state to an anti-parallel state, so that a high-resistance state is formed, thus a binary digit “1” is written into the MTJ. When the MTJ is in the anti-parallel state, the write current is inputted along the vertical direction of the MTJ from top to bottom, the magnetization direction of the second ferromagnetic sub-layer 33 is firstly reversed; due to the ferromagnetic coupling effect, the magnetization direction of the first ferromagnetic sub-layer 31 is correspondingly reversed with that of the second ferromagnetic sub-layer 33, the MTJ transforms from the anti-parallel state to the parallel state, so that a low-resistance state is formed, thus a binary digit “0” is written into the MTJ. Due to the iridium electrode material, the MTJ has a characteristic of high TMR. The double-free-layer structure is conductive to reducing the write current so as to achieve low write power consumption. When a read current is inputted along the vertical direction of the MTJ, the data are read out by the tunneling magnetoresistance effect. The magnetization direction of every ferromagnetic layer is shown in FIG. 6, wherein the magnetization direction of the first ferromagnetic sub-layer 31 is as same as the magnetization direction of the second ferromagnetic sub-layer 33, each of which is able to be parallel to a paper surface toward a left or right side of FIG. 6. In FIG. 6, the magnetization direction of the second ferromagnetic layer 5 is parallel to the paper surface toward the right side of FIG. 6. A direction of the write current and a direction of the read current are parallel to each other, each of which is parallel to the paper surface from top to bottom or from bottom to top.

In the sixth embodiment, the first iridium layer 1 is made from an PtIr alloy and has a thickness of 20 nm; the first ferromagnetic sub-layer 31 is made from an Fe metal element and has a thickness of 0.8 nm; the non-magnetic insertion layer 32 is made from a TiOₓ material and has a thickness of 0.2 nm; the second ferromagnetic sub-layer 33 is made from an Fe metal element and has a thickness of 1 nm; the tunneling barrier layer 4 is made from an AlOₓ material and has a thickness of 1 nm; the second ferromagnetic layer 5 is made from a cobalt platinum (CoPt) alloy and has a thickness of 6 nm; and the second iridium layer 7 is made from an PtIr alloy and has a thickness of 30 nm.

In the third embodiment, through molecular beam epitaxy, magnetron sputtering and other methods, in a bottom-up order, the second iridium layer 7, the second ferromagnetic layer 5, the tunneling barrier layer 4, the second ferromagnetic sub-layer 33, the non-magnetic insertion layer 32, the first ferromagnetic sub-layer 31, and the first iridium layer 1 are deposited on a substrate in sequence; and then a subsequent protection and anti-oxidation treatment is performed; and then electrodes are respectively introduced to the vertical direction of the second iridium layer 7 and the first iridium layer 1 for inputting the read current, while a direction of the write current is parallel to a direction of the read current, each of which is parallel to the paper surface from top to bottom or from bottom to top; and finally, etching is preformed to obtain the MTJ, wherein a cross section of the MTJ is circular or elliptical.

It should be noted that, although the present invention has been described in detail with reference to the embodiments, those skilled in the art should understand that the modifications and equivalents of the technical solutions of the present invention do not departing from the spirit and scope of the technical solutions of the present invention, all of which fall within the protective scope of the claims of the present invention.

What is claimed is:

1. A magnetic tunnel junction (MTJ), which comprises a first non-magnetic layer, a first ferromagnetic layer, a tunneling barrier layer, a second ferromagnetic layer and a second non-magnetic layer from top to bottom in sequence, wherein:
the first non-magnetic layer is configured to protect the first ferromagnetic layer from being oxidized;
the first ferromagnetic layer is a free layer with a reversible magnetization direction which is reversed with a spin transfer torque by inputting a write current along a vertical direction of the MTJ;
the tunneling barrier layer is configured to generate a tunneling current;
the second ferromagnetic layer is a reference layer with a fixed magnetization direction;
the second non-magnetic layer is configured to optimize a growth process of the second ferromagnetic layer;
when the write current is inputted along the vertical direction of the MTJ from top to bottom, the MTJ transforms from an anti-parallel state to a parallel state, the magnetization direction of the free layer is parallel to the magnetization direction of the reference layer, a low-resistance state is formed, a binary digit “0” is written into the MTJ; and when the write current is inputted along the vertical direction of the MTJ from bottom to up, the MTJ transforms from the parallel state to the anti-parallel state, the magnetization direction of the free layer is anti-parallel to the magnetization direction of the reference layer, a high-resistance state is formed, a binary digit “1” is written into the MTJ, thereby achieve data writing;
a read current is inputted along the vertical direction of the MTJ, for achieving data read-out, wherein a direction of the read current is parallel to a direction of the write current.

2. The MTJ, as recited in claim 1, wherein:
the first non-magnetic layer is a first iridium layer which acts as a top electrode and a capping layer for protecting the first ferromagnetic layer from being oxidized;
the second non-magnetic layer is a second iridium layer which acts as a bottom electrode and a seed layer for optimizing the growth process of the second ferromagnetic layer.

3. The MTJ, as recited in claim 1, wherein:
the first non-magnetic layer comprises a first iridium layer and a first tungsten layer from top to bottom in sequence, wherein the first iridium layer is a top electrode, and the first tungsten layer is a capping layer for protecting the first ferromagnetic layer from being oxidized;
the second non-magnetic layer comprises a second tungsten layer and a second iridium layer from top to bottom in sequence, wherein the second tungsten layer is a seed layer for optimizing the growth process of the second ferromagnetic layer, and the second iridium layer is a bottom electrode.

4. The MTJ, as recited in claim 2, wherein:
the first ferromagnetic layer comprises a first ferromagnetic sub-layer, a non-magnetic insertion layer and a second ferromagnetic sub-layer, wherein the non-magnetic insertion layer is configured to magnetic coupling between the first ferromagnetic sub-layer and the second ferromagnetic sub-layer;
when the write current is inputted along the vertical direction of the MTJ from top to bottom, a magnetization direction of the second ferromagnetic sub-layer is firstly reversed, a magnetization direction of the first ferromagnetic sub-layer is correspondingly reversed with the magnetization direction of the second ferromagnetic sub-layer due to ferromagnetic coupling effect, the MTJ transforms from the anti-parallel state to the parallel state, the low-resistance state is formed, and the binary digit “0” is written into the MTJ;
when the write current is inputted along the vertical direction of the MTJ from bottom to top, the magnetization direction of the first ferromagnetic sub-layer is firstly reversed, the magnetization direction of the second ferromagnetic sub-layer is correspondingly reversed with the magnetization direction of the first ferromagnetic sub-layer due to the ferromagnetic coupling effect, the MTJ transforms from the parallel state to the anti-parallel state, the high-resistance state is formed, and the binary digit “1” is written into the MTJ;
the magnetization direction of the first ferromagnetic sub-layer is as same as the magnetization direction of the second ferromagnetic sub-layer.

5. The MTJ, as recited in claim 3, wherein:
the first ferromagnetic layer comprises a first ferromagnetic sub-layer, a non-magnetic insertion layer and a second ferromagnetic sub-layer, wherein the non-magnetic insertion layer is configured to magnetic coupling between the first ferromagnetic sub-layer and the second ferromagnetic sub-layer;
when the write current is inputted along the vertical direction of the MTJ from top to bottom, a magnetization direction of the second ferromagnetic sub-layer is firstly reversed, a magnetization direction of the first ferromagnetic sub-layer is correspondingly reversed with the magnetization direction of the second ferromagnetic sub-layer due to ferromagnetic coupling effect, the MTJ transforms from the anti-parallel state to the parallel state, the low-resistance state is formed, and the binary digit “0” is written into the MTJ;
when the write current is inputted along the vertical direction of the MTJ from bottom to top, the magnetization direction of the first ferromagnetic sub-layer is firstly reversed, the magnetization direction of the second ferromagnetic sub-layer is correspondingly reversed with the magnetization direction of the first ferromagnetic sub-layer due to the ferromagnetic coupling effect, the MTJ transforms from the parallel state to the anti-parallel state, the high-resistance state is formed, and the binary digit “1” is written into the MTJ;
the magnetization direction of the first ferromagnetic sub-layer is as same as the magnetization direction of the second ferromagnetic sub-layer.

6. The MTJ, as recited in claim 2, wherein: every iridium layer with a thickness in a range of 0.2 to 100 nm is made from an iridium metal element or an iridium metal alloy; every tungsten layer with a thickness in a range of 0.2 to 10 nm is made from a tungsten metal element or a tungsten metal alloy; every ferromagnetic layer with a thickness in a range of 0.2 to 10 nm is made from a ferromagnetic material; the tunneling barrier layer with a thickness in a range of 0.2 to 10 nm is made from an oxide.

7. The MTJ, as recited in claim 3, wherein: every iridium layer with a thickness in a range of 0.2 to 100 nm is made from an iridium metal element or an iridium metal alloy; every tungsten layer with a thickness in a range of 0.2 to 10 nm is made from a tungsten metal element or a tungsten metal alloy; every ferromagnetic layer with a thickness in a range of 0.2 to 10 nm is made from a ferromagnetic material; the tunneling barrier layer with a thickness in a range of 0.2 to 10 nm is made from an oxide.

8. The MTJ, as recited in claim 4, wherein: every iridium layer with a thickness in a range of 0.2 to 100 nm is made from an iridium metal element or an iridium metal alloy; every tungsten layer with a thickness in a range of 0.2 to 10 nm is made from a tungsten metal element or a tungsten metal alloy; every ferromagnetic layer with a thickness in a range of 0.2 to 10 nm is made from a ferromagnetic material; the tunneling barrier layer with a thickness in a range of 0.2 to 10 nm is made from an oxide; the non-magnetic insertion layer with a thickness in a range of 0.2 to 10 nm is a non-magnetic thin layer which is made from an oxide, a non-magnetic metal, an alloy of the non-magnetic metal, a nonmetal, or a compound of the nonmetal.

9. The MTJ, as recited in claim 5, wherein: every iridium layer with a thickness in a range of 0.2 to 100 nm is made from an iridium metal element or an iridium metal alloy; every tungsten layer with a thickness in a range of 0.2 to 10 nm is made from a tungsten metal element or a tungsten metal alloy; every ferromagnetic layer with a thickness in a range of 0.2 to 10 nm is made from a ferromagnetic material; the tunneling barrier layer with a thickness in a range of 0.2 to 10 nm is made from an oxide; the non-magnetic insertion layer with a thickness in a range of 0.2 to 10 nm is a non-magnetic thin layer which is made from an oxide, a non-magnetic metal, an alloy of the non-magnetic metal, a nonmetal, or a compound of the nonmetal.

10. The MTJ, as recited in claim 6, wherein: the iridium metal alloy is iridium manganese alloy, iridium gold alloy or platinum iridium alloy; the tungsten metal alloy is copper tungsten alloy, tantalum tungsten alloy or molybdenum tungsten alloy; the oxide made into the tunneling barrier layer is magnesium oxide, aluminum oxide, titanium oxide, or silicon oxide.

11. The MTJ, as recited in claim 7, wherein: the iridium metal alloy is iridium manganese alloy, iridium gold alloy or platinum iridium alloy; the tungsten metal alloy is copper tungsten alloy, tantalum tungsten alloy or molybdenum tungsten alloy; the oxide made into the tunneling barrier layer is magnesium oxide, aluminum oxide, titanium oxide, or silicon oxide.

12. The MTJ, as recited in claim 8, wherein: the iridium metal alloy is iridium manganese alloy, iridium gold alloy or platinum iridium alloy; the tungsten metal alloy is copper tungsten alloy, tantalum tungsten alloy or molybdenum tungsten alloy; the oxide made into the tunneling barrier layer is magnesium oxide, aluminum oxide, titanium oxide, or silicon oxide; the oxide made into the non-magnetic insertion layer is MgO, AlOx, TiOx or SiOx, the non-magnetic metal made into the non-magnetic insertion layer is Ta, Ru or Cu, the nonmetal made into the non-magnetic insertion layer is Si or Ge.

13. The MTJ, as recited in claim 9, wherein: the iridium metal alloy is iridium manganese alloy, iridium gold alloy or platinum iridium alloy; the tungsten metal alloy is copper tungsten alloy, tantalum tungsten alloy or molybdenum tungsten alloy; the oxide made into the tunneling barrier layer is magnesium oxide, aluminum oxide, titanium oxide, or silicon oxide; the oxide made into the non-magnetic insertion layer is MgO, AlOx, TiOx or SiOx, the non-magnetic metal made into the non-magnetic insertion layer is Ta, Ru or Cu, the nonmetal made into the non-magnetic insertion layer is Si or Ge.

14. A magnetic tunnel junction (MTJ), which comprises a first non-magnetic layer, a first ferromagnetic layer, a tunneling barrier layer, a second ferromagnetic layer and a second non-magnetic layer from top to bottom in sequence, wherein:
the first non-magnetic layer is configured to protect the first ferromagnetic layer from being oxidized;
the first ferromagnetic layer is a reference layer with a fixed magnetization direction;
the tunneling barrier layer is configured to generate a tunneling current;
the second ferromagnetic layer is a free layer with a reversible magnetization direction which is reversed with a spin orbit torque by inputting a write current along a horizontal direction where the second non-magnetic layer is located;
the second non-magnetic layer is configured to optimize a growth process of the second ferromagnetic layer;
when the write current is inputted along the horizontal direction where the second non-magnetic layer is located from left to right, the MTJ transforms from an anti-parallel state to a parallel state, the magnetization direction of the free layer is parallel to the magnetization direction of the reference layer, a low-resistance state is formed, a binary digit “0” is written into the MTJ; and when the write current is inputted along the horizontal direction where the second non-magnetic layer is located from right to left, the MTJ transforms from the parallel state to the anti-parallel state, the magnetization direction of the free layer is anti-parallel to the magnetization direction of the reference layer, a high-resistance state is formed, a binary digit “1” is written into the MTJ, thereby achieve data writing;
a read current is inputted along the vertical direction of the MTJ, for achieving data read-out;
the magnetization direction of every ferromagnetic layer, a direction of the write current and a direction of the read current are perpendicular to each other.

15. The MTJ, as recited in claim 14, wherein:
the first non-magnetic layer is a first iridium layer which acts as a top electrode and a capping layer for protecting the first ferromagnetic layer from being oxidized;
the second non-magnetic layer is a second iridium layer which acts as a bottom electrode and a seed layer for optimizing the growth process of the second ferromagnetic layer.

16. The MTJ, as recited in claim 14, wherein:
the first non-magnetic layer comprises a first iridium layer and a first tungsten layer from top to bottom in sequence, wherein the first iridium layer is a top electrode, and the first tungsten layer is a capping layer for protecting the first ferromagnetic layer from being oxidized;
the second non-magnetic layer comprises a second tungsten layer and a second iridium layer from top to bottom in sequence, wherein the second tungsten layer is a seed layer for optimizing the growth process of the second ferromagnetic layer, and the second iridium layer is a bottom electrode.

17. The MTJ, as recited in claim 14, wherein: every iridium layer with a thickness in a range of 0.2 to 100 nm is made from an iridium metal element or an iridium metal alloy; every tungsten layer with a thickness in a range of 0.2 to 10 nm is made from a tungsten metal element or a tungsten metal alloy; every ferromagnetic layer with a thickness in a range of 0.2 to 10 nm is made from a ferromagnetic material; the tunneling barrier layer with a thickness in a range of 0.2 to 10 nm is made from an oxide.

18. The MTJ, as recited in claim 15, wherein: every iridium layer with a thickness in a range of 0.2 to 100 nm is made from an iridium metal element or an iridium metal alloy; every tungsten layer with a thickness in a range of 0.2 to 10 nm is made from a tungsten metal element or a tungsten metal alloy; every ferromagnetic layer with a thickness in a range of 0.2 to 10 nm is made from a ferromagnetic material; the tunneling barrier layer with a thickness in a range of 0.2 to 10 nm is made from an oxide.

19. The MTJ, as recited in claim 17, wherein: the iridium metal alloy is iridium manganese alloy, iridium gold alloy or platinum iridium alloy; the tungsten metal alloy is copper tungsten alloy, tantalum tungsten alloy or molybdenum tungsten alloy; the oxide made into the tunneling barrier layer is magnesium oxide, aluminum oxide, titanium oxide, or silicon oxide.

20. The MTJ, as recited in claim 18, wherein: the iridium metal alloy is iridium manganese alloy, iridium gold alloy or platinum iridium alloy; the tungsten metal alloy is copper tungsten alloy, tantalum tungsten alloy or molybdenum tungsten alloy; the oxide made into the tunneling barrier layer is magnesium oxide, aluminum oxide, titanium oxide, or silicon oxide.
